(19) United States
(12) Patent Application Publication
(10) Pub. No.: US 2001/0051424 A1
(43) Pub. Date: Dec. 13, 2001

(54) METHOD OF FORMING AN OPENING IN A DIELECTRIC LAYER IN INTEGRATED CIRCUIT

(76) Inventors: ANDREW LIN, MIAO-LI HSIEN (TW); SHIH-MING LAN, HSINCHU (TW); HSIEN-LIANG MENG, HSINCHU (TW)

Correspondence Address: J C Patents Inc, 4 Venture, Suite 250, Irvine, CA, 92618, US

(21) Appl. No.: 09/250,619

(22) Filed: Feb. 16, 1999

(30) Foreign Application Priority Data
Sep. 2, 1998 (TW) 871145525

(51) Int. Cl. H01L 21/4763

(52) U.S. Cl. 438/632; 438/637; 438/624

(57) ABSTRACT

A semiconductor fabrication method is provided for forming an opening in a dielectric layer, which can help the resulting opening to be more accurately dimensioned to its specified size without being overly large. By this method, a first dielectric layer is formed from undoped silicate glass (USG) over the substrate, then a second dielectric layer is formed from an acid-resistant dielectric material over the first dielectric layer, and a third dielectric layer is subsequently formed from a thermal-flow dielectric material over the third dielectric layer. A thermal-flow process is performed to slightly planarize the third dielectric layer. Next, an isotropic etch-back process is performed to remove entirely the third dielectric layer and to remove partly the second dielectric layer partly until reaching a predefined plane in the second dielectric layer. A photolithographic and etching process is then performed to form an opening in the combined structure of the first and second dielectric layers. Finally, the entire photoresist layer is removed by using an acidic chemical agent that that cannot etch the acid-resistant dielectric material used to form the second dielectric layer. By this method, the top surface of the overall dielectric layer is highly planarized, and the opening in the dielectric layer is more accurately dimensioned than that of the prior art. The resulting integrated circuit is thus more reliable.

### CROSS-REFERENCE TO RELATED APPLICATION

This application claims the priority benefit of Taiwan application serial no. 87114525, filed Sep. 2, 1998, the full disclosure of which is incorporated herein by reference.

### BACKGROUND OF THE INVENTION

1. Field of the Invention

This invention relates to semiconductor fabrication technology, and more particularly, to a method of forming an opening in a dielectric layer in integrated circuit, which not only can help the resulting opening be more accurately dimensioned, but also can allow the dielectric layer to be highly planarized.

2. Description of Related Art

FIG. 1 is a schematic sectional diagram showing the forming of an opening 16 in a dielectric layer 13 formed over a semiconductor substrate 10. The dielectric layer 13 is a two-layer structure including a layer of undoped silicate glass (USG) 11 and a layer of borophosphosilicate glass (BPSG) 12. The USG layer 11 is formed for the purpose of preventing the boron and phosphorus atoms in the BPSG layer 12 from diffusing into the substrate 10. The BPSG layer 12 has a thermal-flow characteristic with a low glass transition temperature that can help the top surface 14 of the dielectric layer 13 to be planarized. The opening 16 is formed through a photolithographic and etching process to remove a selected portion of the dielectric layer 13 until the top surface of the substrate 10 is exposed.

One drawback to the foregoing method, however, is that the resulting opening 16 may be too big because the BPSG layer 12 is only weakly resistant to the acid used to remove the photoresist layer used in the photolithographic process. The overly large size of the opening may be acceptable in low-integration structures, but is unacceptable in high-integration structures since the opening may extend so far as to expose other conductive elements or the neighboring opening in the same integrated circuit, thus causing short-circuiting in the integrated circuit. There exists, therefore, a need in the semiconductor industry for a solution to this problem.

Details of the steps involved in the method of fabricating the wafer of FIG. 1 are described step by step with reference to FIGS. 2A-2E.

Referring first to FIG. 2A, in the initial step, a semiconductor substrate 20 is prepared. The substrate 20 is already formed with some components which furrow the top surface of the substrate 20. A thin USG layer 21 is then formed over the substrate 20, preferably through an APCVD (atmospheric-pressure chemical-vapor deposition) process. Next, a thick BPSG layer 23 is formed over the USG layer 21, preferably from a composition of BPSG containing from 0.5 wt % to 10 wt % of phosphorus and from 0.5 wt % to 10 wt % of boron, through an APCVD process to a thickness of from 500 Å to 20,000 Å (angstrom). Due to the originally furrowed surface of the substrate 20, the resulting BPSG layer 23 is also correspondingly furrowed in its top surface, as demonstratively illustrated in FIG. 2A.

Referring further to FIG. 2B, in the subsequent step, a thermal-flow process is performed at a temperature of from 850° C. to 950° C. (i.e., the glass transition temperature of BPSG) on the wafer. Through this process, the BPSG layer 23 is liquidized into flowable state that allows its top surface to be slightly planarized, though not completely, as demonstratively illustrated in FIG. 2B.

Referring next to FIG. 2C, in the subsequent step, an isotropic etch-back process is performed on the wafer to etch away a part of the surface of the BPSG layer 23 until reaching a predefined plane in the BPSG layer 23. Through this process, the top surface of the remaining BPSG layer 23 is substantially planarized as demonstratively illustrated in FIG. 2C.

Referring further to FIG. 2D, in the subsequent step, a photolithographic process is performed to form a photoresist layer 25 over the BPSG layer 23 in such a manner as to expose only a selected part of the BPSG layer 23 where the intended opening is to be formed. Then, with the photoresist layer 25 serving as mask, an etching process, such as an anisotropic dry-etching process, is performed on the wafer so as to etch away the unmasked portions of the BPSG layer 23 and the underlying USG layer 21 until the top surface of the substrate 20 is exposed. Through this process, an opening 26 is formed in the combined structure of the USG layer 21 and the BPSG layer 23.

Referring next to FIG. 2E, in the subsequent step, the photoresist layer 25 is removed by using an acidic chemical agent such as RCA. However, since BPSG is only weakly resistant to such an acidic chemical agent, the sidewalls of the opening 26 in the BPSG layer 23 are further etched away by the acidic chemical agent, thus further widening the opening (which is here designated instead by the reference numeral 26a for distinguishing purpose). The final, resulting opening 26a is thus overly large. The excessive size of the opening may be acceptable in low-integration structures, but is unacceptable in high-integration structures since it may extend to expose other conductive elements or the neighboring opening in the same integrated circuit, thus causing short-circuiting in the integrated circuit.

### SUMMARY OF THE INVENTION

It is therefore an objective of the present invention to provide a semiconductor fabrication method for forming an opening in a dielectric layer in integrated circuit, which not only can help the resulting opening to be more accurately dimensioned, but also can allow the dielectric layer to be highly planarized.

In accordance with the foregoing and other objectives of the present invention, a semiconductor fabrication method for forming an opening in a dielectric layer in an integrated circuit is provided. By the method of the invention, a first dielectric layer is formed from USG over the substrate, a second dielectric layer is formed from an acid-resistant dielectric material over the first dielectric layer, and then a third dielectric layer is formed from a thermal-flow dielectric material over the third dielectric layer. Subsequently, a thermal-flow process is performed at or above the glass transition temperature of the thermal-flow dielectric material used to form the third dielectric layer, whereby the top surface of the third dielectric layer is slightly planarized. After this, an isotropic etch-back process is performed to entirely remove the third dielectric layer and partly removed the second dielectric layer until reaching a predefined plane in the second dielectric layer. Subsequently, a photolithographic and etching process is performed to remove selected portions of the combined structure of the first and second dielectric layers until the substrate is exposed, whereby an opening is formed through the first and second dielectric layers. Finally, the entire photoresist layer is removed by using an acidic chemical agent that cannot etch the acid-resistant dielectric material used to form the second dielectric layer.

By the method of the invention, not only that the top surface of the dielectric layer is highly planarized, but also that the opening in the dielectric layer is more accurately dimensioned than the prior art. The resulting integrated circuit is thus more reliable.

### BRIEF DESCRIPTION OF DRAWINGS

The invention can be more fully understood by reading the following detailed description of the preferred embodiments, with reference made to the accompanying drawings, wherein:

FIG. 1 is a schematic, sectional diagram used to depict the forming of an opening in a dielectric layer in an integrated circuit;

FIGS. 2A-2E are schematic, sectional diagrams used to depict the steps involved in a conventional method for forming an opening in a dielectric layer; and

FIGS. 3A-3E are schematic, sectional diagrams used to depict the steps involved in the method of the invention for forming an opening in a dielectric layer.

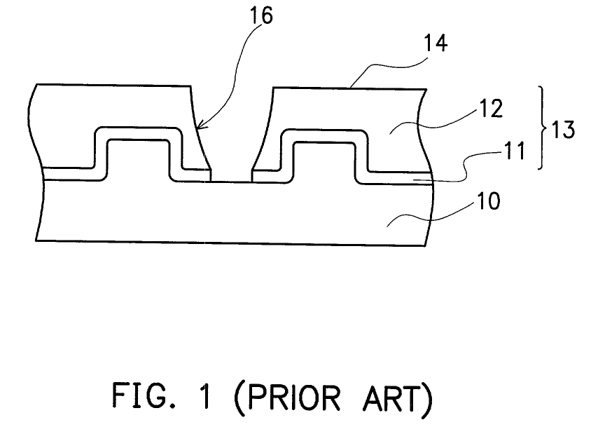

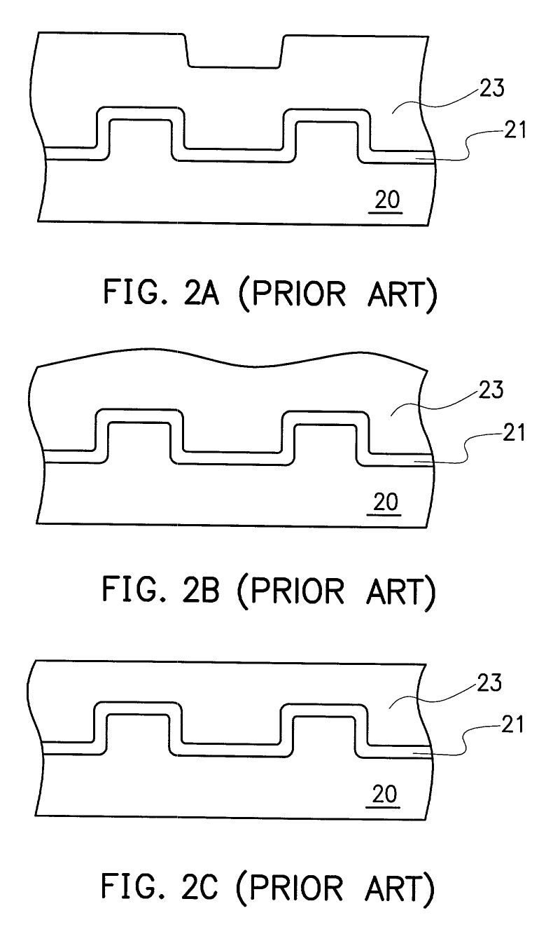

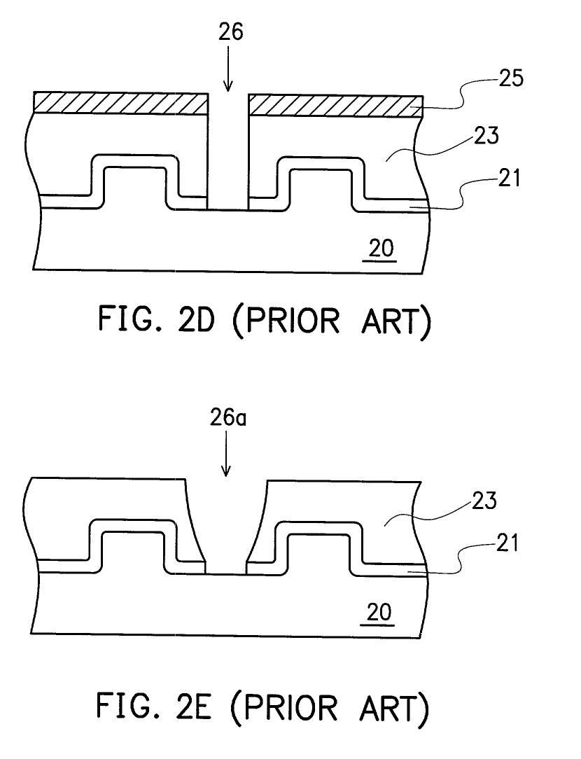

### DETAILED DESCRIPTION OF PREFERRED EMBODIMENTS

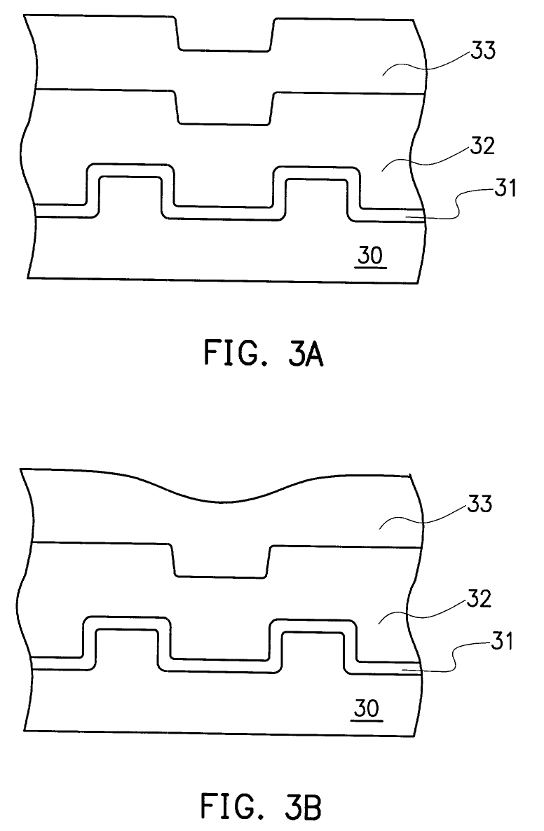

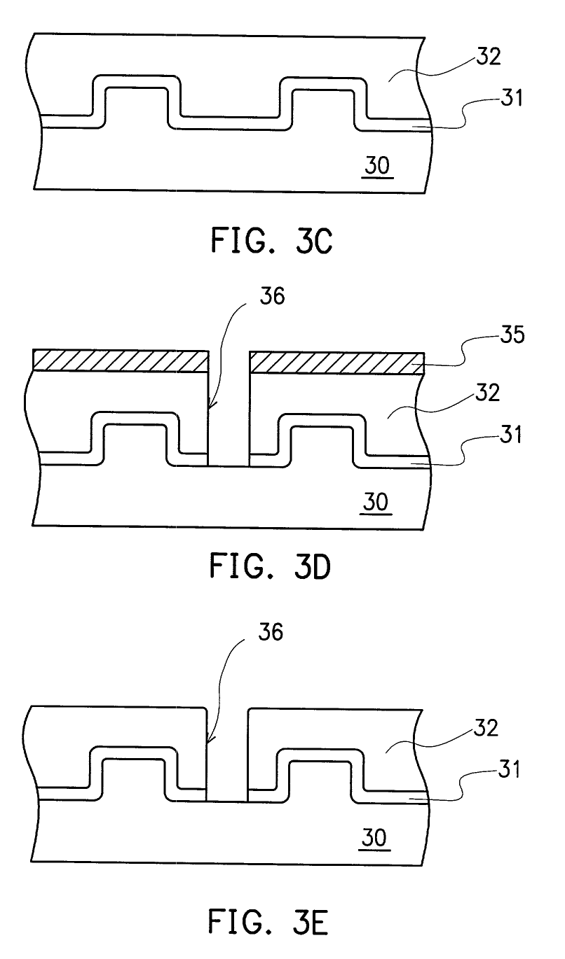

FIGS. 3A-3E are schematic, sectional diagrams used to depict the steps involved in the method of the invention for forming an opening in a dielectric layer in an IC device.

Referring first to FIG. 3A, in the initial step, a semiconductor substrate 30 is prepared. The substrate 30 is already formed with some components which furrow the top surface of the substrate 30.

A first dielectric layer 31 is then formed over the substrate 30, preferably from undoped silicate glass (USG) through an APCVD (atmospheric-pressure chemical-vapor deposition) process.

Next, a second dielectric layer 32 is formed over the first dielectric layer 31 to a thickness of from 500 Å to 20,000 Å. It is an important aspect of the invention that the second dielectric layer 32 is formed from an acid-resistant dielectric material, such as borosilicate glass (BSG) containing from 0.5 wt % to 10 wt % of boron, or phosphosilicate glass (PSG) containing from 0.5 wt % to 10 wt % of phosphorus, or USG. The acid-resistant dielectric material can be deposited through, for example, an APCVD process over the first dielectric layer 31 to form the second dielectric layer 32.

Subsequently, a third dielectric layer 33 is formed over the second dielectric layer 32 to a thickness of from 500 Å to 20,000 Å. It is another important aspect of the invention that the third dielectric layer 33 is formed from a thermal-flow dielectric layer, such as BPSG containing from 0.5 wt % to 10 wt % of phosphorus and from 0.5 wt % to 10 wt % of boron, or PSG containing from 0.5 wt % to 10 wt % of phosphorus. The thermal-flow dielectric material can be deposited through, for example, an APCVD process over the second dielectric layer 32 to form the third dielectric layer 33.

Due to the originally furrowed surface of the substrate 30, the topmost dielectric layer, i.e., the third dielectric layer 33, is also correspondingly furrowed in its top surface, as demonstratively illustrated in FIG. 3A.

Referring further to FIG. 3B, in the subsequent step, a thermal-flow process is performed at a temperature of from 850° C. to 950° C. (i.e., the glass transition temperature of the BPSG or PSG used to form the third dielectric layer 33) on the wafer. Through this process, the third dielectric layer 33 is liquidized into flowable state that allows its top surface to be slightly, though not completely, planarized as demonstratively illustrated in FIG. 3B.

Referring next to FIG. 3C, in the subsequent step, an isotropic etch-back process is performed on the wafer until reaching a predefined plane in the second dielectric layer 32. Through this process, the third dielectric layer 33 is entirely removed, and further, an upper part of the second dielectric layer 32 is removed to provide a highly planarized top surface, as demonstratively illustrated in FIG. 3C.

Referring further to FIG. 3D, in the subsequent step, a photolithographic process is performed to form a photoresist layer 35 over the planarized second dielectric layer 32 in such a manner as to expose only a selected part of the second dielectric layer 32 where the intended opening is to be formed. Then, an etching process, such as an anisotropic dry-etching process, is performed on the wafer to etch away the unmasked portions of the second dielectric layer 32 and the underlying first dielectric layer 31 until the top surface of the substrate 30 is exposed. Through this process, an opening 36 is formed in the combined structure of the first and second dielectric layers 31, 32.

Referring next to FIG. 3E, in the subsequent step, the photoresist layer 35 is removed by using an acidic chemical agent, such as RCA. Since the second dielectric layer 32 is formed from an acid-resistant dielectric material mentioned earlier, the acidic chemical agent used for the removal of the photoresist layer 35 cannot etch into the sidewall of the opening 36 in the second dielectric layer 32. Therefore, after the photoresist layer 35 is removed, the opening 36 substantially retains its original size as formed in the foregoing photolithographic and etching process without being overly large as in the case of the prior art. The quality of the resulting IC device can thus be more assured.

It is to be noted that, in the case of USG being selected to form the second dielectric layer 32, since the first dielectric layer 31 is also formed from USG, these two dielectric layers 31, 32 can be formed together through a single deposition process to form a single layer of USG to a thickness of from 500 Å to 20,000 Å. This alteration in the process can also help prevent the resulting opening from being overly large.

Furthermore, the method of the invention can be used to form any kind of opening in a dielectric layer, such as a contact hole or a via.

In conclusion, the method of the invention has the following advantages over the prior art.

(1) First, the method of the invention utilizes an acid-resistant dielectric material instead of BPSG to form the dielectric layer in which the opening is formed, thus allowing the resulting opening to be more accurately dimensioned to its specified size.

(2) Second, the method of the invention utilizes a thermal-flow dielectric material with a low glass transition temperature, such as BPSG or PSG, to help planarize the top surface of the dielectric layer in which the opening is formed, thus allowing the overall dielectric layer to be highly planarized.

Therefore, by the method of the invention, the top surface of the dielectric layer is highly planarized, and the opening in the dielectric layer is more accurately dimensioned than the prior art. The resulting IC device is undoubtedly more reliable.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor fabrication method, comprising the steps of:
preparing a semiconductor substrate;
forming a first dielectric layer from USG over the substrate;
forming a second dielectric layer from an acid-resistant dielectric material over the first dielectric layer;
forming a third dielectric layer from a thermal-flow dielectric material over the third dielectric layer;
performing a thermal-flow process on the third dielectric layer;
performing an etch-back process to remove the third dielectric layer entirely and the second dielectric layer partly until reaching a predefined plane in the second dielectric layer;
performing a photolithographic process to form a photoresist layer over the second dielectric layer in such a manner as to unmask only a selected part of the combined structure of the first and second dielectric layers;
with the photoresist layer serving as mask, performing an etching process to etch away the unmasked portions of the combined structure of the first and second dielectric layers until the substrate is exposed so as to form an opening through the combined structure of the first and second dielectric layers; and
removing the entire photoresist layer by using an acidic chemical agent that cannot etch the acid-resistant dielectric material used to form the second dielectric layer.

2. The method of claim 1, wherein the acid-resistant dielectric material used to form the second dielectric layer is a composition of BSG.

3. The method of claim 2, wherein the composition of BSG contains from 0.5 wt % to 10 wt % of boron.

4. The method of claim 1, wherein the acid-resistant dielectric material used to form the second dielectric layer is a composition of PSG.

5. The method of claim 4, wherein the composition of PSG contains from 0.5 wt % to 10 wt % of phosphorus.

6. The method of claim 1, wherein the acid-resistant dielectric material is USG.

7. The method of claim 1, wherein the acid-resistant dielectric material used to form the second dielectric layer is deposited to a thickness of from 500 Å to 20,000 Å.

8. The method of claim 1, wherein the thermal-flow dielectric material used to form the third dielectric layer is a composition of BPSG.

9. The method of claim 8, wherein the composition of BPSG contains from 0.5 wt % to 10 wt % of phosphorus and from 0.5 wt % to 10 wt % of boron.

10. The method of claim 1, wherein the thermal-flow dielectric material used to form the third dielectric layer is a composition of PSG.

11. The method of claim 10, wherein the composition of PSG contains from 0.5 wt % to 10 wt % of phosphorus.

12. The method of claim 1, wherein the thermal-flow dielectric material used to form the third dielectric layer is deposited to a thickness of from 500 Å to 20,000 Å.

13. The method of claim 1, wherein the second dielectric layer is formed through an APCVD process.

14. The method of claim 1, wherein the third dielectric layer is formed through an APCVD process.

15. The method of claim 1, wherein the etch-back process on the third dielectric layer is an isotropic etch-back process.

16. The method of claim 1, wherein the etching process on the second dielectric layer and the first dielectric layer to form the opening is an anisotropic dry-etching process.

17. A semiconductor fabrication method, comprising the steps of:
preparing a semiconductor substrate,
forming a USG layer over the substrate;
forming a thermal-flow dielectric layer from a thermal-flow dielectric material over the USG layer;
performing a thermal-flow process on the thermal-flow dielectric layer;
performing an etch-back process to remove the thermal-flow dielectric layer entirely and the USG layer partly until reaching a predefined plane in the USG layer;
performing a photolithographic process to form a photoresist layer over the USG layer in such a manner as to unmask only a selected part of the USG layer;
with the photoresist layer serving as mask, performing an etching process to etch away the unmasked portions of the USG layer until the substrate is exposed so as to form an opening through the USG layer; and
removing the entire photoresist layer by using an acidic chemical agent that cannot etch the USG layer.

18. The method of claim 17, wherein the USG layer is formed to thickness of from 500 Å to 20,000 Å.
